(19) United States
(12) Patent Application Publication
(10) Pub. No.: US 2017/0047275 A1
(43) Pub. Date: Feb. 16, 2017

(54) REDUCING LEAD STRESS IN MICRO-ELECTRONIC PACKAGES

(71) Applicant: NXP B.V., Eindhoven (NL)

(72) Inventor: Wiwat Tanwongwan, Chatuchak (TH)

(21) Appl. No.: 14/823,486

(22) Filed: Aug. 11, 2015

(51) Int. Cl. H01L 23/495; H01L 21/56; H01L 21/52

(52) U.S. Cl. CPC H01L 23/49586; H01L 23/49513; H01L 23/49558; H01L 21/52; H01L 21/563

(57) ABSTRACT

Consistent with an example embodiment, there is a semiconductor device that comprises a lead frame assembly having a non-conductive material (NCM) sheet placed on a location of the lead frame assembly. A device die having a length, width, and thickness, is attached to the NCM sheet, the device die being attached to the NCM with an adhesive. The NCM sheet has a length and width greater than the length and width of the device die and the NCM sheet has a thickness less than the thickness of the device die. The NCM sheet mitigates wire bond lifting at device die bond pads by reducing bouncing of the wire bond leads owing to stress and movement of the lead frame assembly underneath the device die.

### FIELD

The embodiments of the present disclosure relate to semiconductor device packaging, in particular the reducing of stress of bond connections in the packaging.

### BACKGROUND

The electronics industry continues to rely upon advances in semiconductor technology to realize higher-function devices in more compact areas. These higher-function devices have to survive the stresses incurred during manufacturing and those stresses imposed by their ultimate application by the end user.

### SUMMARY

The present disclosure has been found useful in the packaging of semiconductor devices having increased strength against the breaking of wire bonds owing to lead bouncing and the subsequent lift-off of the ball bond on the device die bond pad.

There are ways of reducing bouncing of a lead, for example by using clamping techniques and lead frame structure design. However, these techniques may add to the cost of the lead frame materials and subsequently increase device cost. Thus, there is a need to overcome and reduce lead bouncing.

The bouncing of lead frame material can be decreased by sandwiching a nonconductive material sheet between the underside surface of the device die and the topside surface of lead frame structure. A resilient material sheet is put onto lead frame structure by appropriate techniques. In various embodiments, a pattern shape and size of the material sheet may be designed to address to different levels of bouncing lead as well.

In an example embodiment, a semiconductor device comprises a lead frame assembly having a non-conductive material (NCM) sheet placed on a location of the lead frame assembly, a device die having a length, width, and thickness is attached to the NCM sheet, the device die being attached to the NCM with an adhesive. The NCM sheet has a length and width greater than the length and width of the device die and the NCM sheet has a thickness less than the thickness of the device die. A feature of this embodiment is the NCM sheet mitigates wire bond lifting at device die bond pads by reducing bouncing of the wire bond leads owing to stress and movement of the lead frame assembly underneath the device die.

In an example embodiment, a semiconductor device is assembled in a leadless package. The leadless package comprises a device die having a length, width, and thickness, the device die having a top-side surface with active circuit elements and an underside surface. A non-conductive material (NCM) sheet has a length and width greater than the length and width of the device die, the NCM is attached to the underside surface of the device die. There is a lead frame assembly, the lead frame assembly having been characterized such that the semiconductor device die attached to the NCM is placed in a cover area and where bonding areas and not-allow bonding areas are defined. The NCM sheet mitigates wire bond lifting at device die bond pads by reducing bouncing of the wire bond leads owing to stress and movement of the lead frame assembly underneath the device die.

In an example embodiment, there is a method for assembling a semiconductor device. The method comprises selecting a lead frame assembly, attaching a NCM sheet in a device die position on the lead frame assembly, attaching a device die onto the NCM sheet, wire bonding the device die to the lead frame assembly, and encapsulating the device die and lead frame assembly. A feature of this embodiment is wherein the pre-determined device die position on the lead frame assembly has been found by a characterization of the lead frame, whereby the pre-determined device die position is a location having substantially reduced stress and displacement with respect to other positions on the lead frame assembly.

The above summaries are not intended to represent each disclosed embodiment, or every aspect, of the present disclosure. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1A-1C illustrate the lifting of the ball bump wire bond on device die pad landing owing to lead bouncing;

FIGS. 2A-2B illustrate the placement of a non-conductive sheet under a device die as it is attached to a lead frame according to embodiments of the present disclosure;

FIGS. 3A-3D illustrate a number of shapes of the non-conductive sheet placed on a lead frame structure according to embodiments of the present disclosure;

FIGS. 4A-4D illustrate a number of views of an example XQFN8 (Extremely Thin Quad Flat Package, No Leads, 8 Terminals) package assembled according to the present disclosure;

FIGS. 5A-5D illustrate a number of views of an example XSON8 (Extremely Thin Small Outline Package, No-Leads, 8 Terminals) package assembled according to the present disclosure

FIGS. 6A-6B show a comparison of an XQFN8 lead frame having a device assembled with and without a non-conductive sheet underneath the device to which a constant static force is applied;

FIG. 7A shows a representation of stress applied onto a device die mounted without a stress-relieving non-conductive sheet according to embodiments of the present disclosure;

FIG. 7B shows a representation of stress applied onto a device die mounted with a stress-relieving non-conductive sheet according to embodiments of the present disclosure;

FIG. 8A shows a representation of the lead bouncing displacement corresponding to the stress depicted in FIG. 7A;

FIG. 8B shows a representation of the lead bouncing displacement corresponding to the stress depicted in FIG. 7B;

FIG. 9 is a flow diagram of an example process of characterizing a lead frame assembly as it is used with NCM sheets according to embodiments of the present disclosure; and

FIG. 10 is a flow diagram of packaging of semiconductor devices according to embodiments of the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present disclosure has been found useful in reducing the stress placed upon wire bonds of a device die encapsulated into a lead less package. The stress causes the lead frame to bend thereby causing lead bouncing. The lead bouncing results in bump ball lift off at the wire bonds. To reduce the likelihood of bump ball lift-off, a device die is placed onto a lead frame assembly onto which a resilient non-conductive material sheet is placed. Bump ball lift-off is the result of a weak inter-metallic bond between the device die bond pad and the bump ball.

The device die may be glued onto this resilient sheet or a die-attach film (DAF) may be used. In a current wire bonding process, placement of device die in a suitable position may reduce lead bouncing, but may be problematic for the variety of devices which may be assembled in a given package type. The present disclosure obviates the need to find a particular optimal position, but enables the user to place the die in more positions on the lead frame structure and yet, have minimal lead bouncing. Further, with some characterization of the lead frame structure (in finding the optimal die placement area) a combination of a preferred placement in combination with the use of the resilient non-conductive material underneath the device die, will substantially enhance the optimization and thereby reduce the incidence of bump ball lift-off. In an example embodiment, a series of design rules may be developed based on empirical data obtained in studies of lead frames, NCM configurations, device die characteristics, etc.

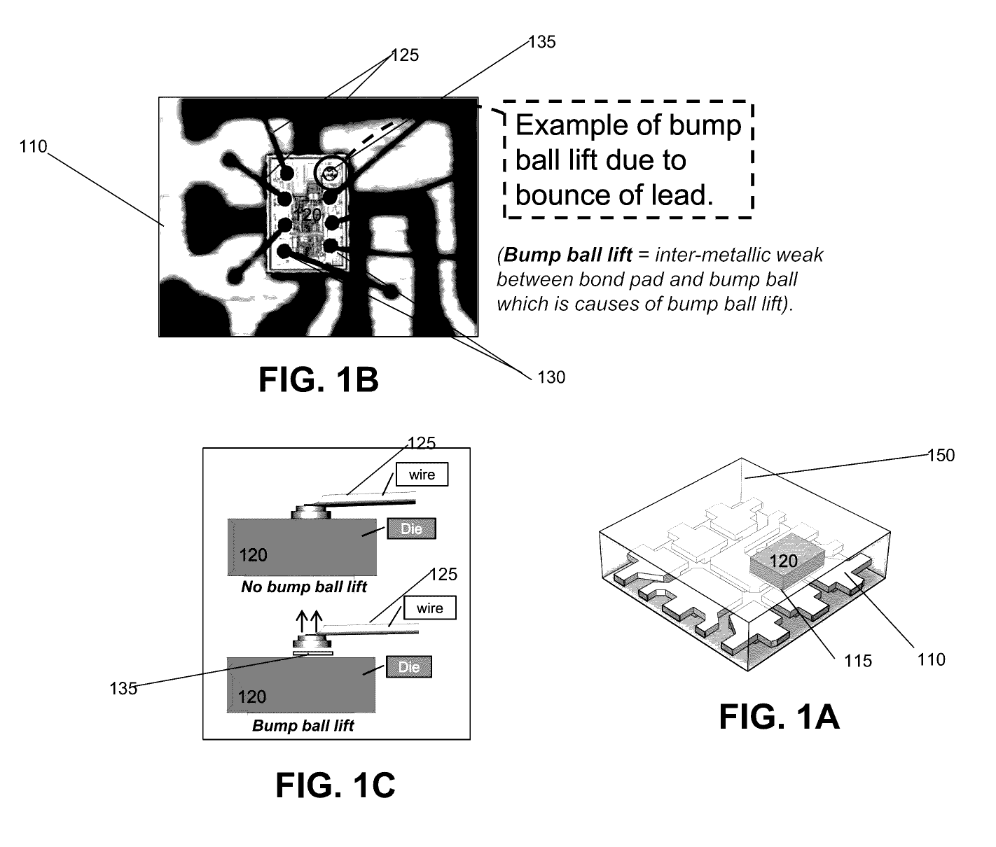

Refer to FIGS. 1A-1C. A device die 120 has been mounted onto a lead frame assembly 110. Wire bonds 125 connect the bond pads 130 to terminals 115 on the lead frame assembly 110. A bump ball lift 135 has occurred owing to lead bouncing.

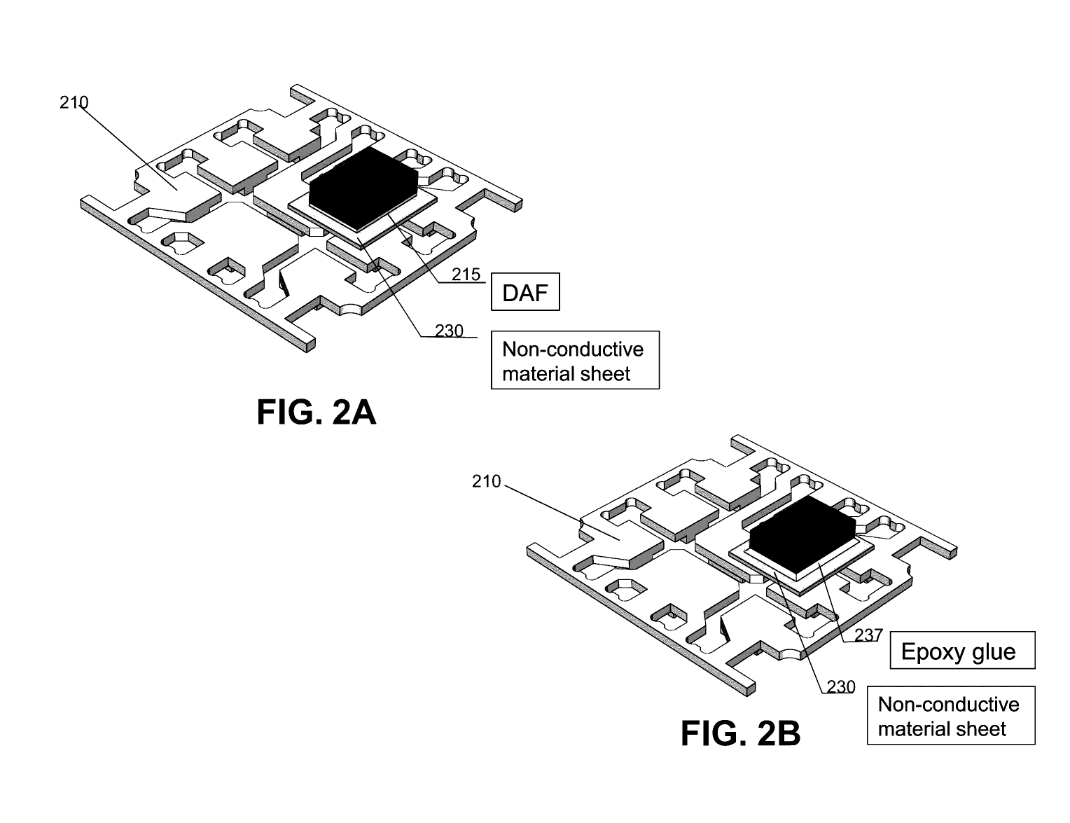

Refer to FIG. 2A. In an example embodiment, a device die 220 has been mounted onto a non-conductive material (NCM) sheet 230. A die-attach film (DAF) 235 is used to attach the device die 220 onto the NCM sheet 230. The NCM sheet 230 is attached to the lead frame assembly 210. Refer to FIG. 2B. In an alternate embodiment, a suitable glue 237, such as an epoxy, is used in lieu of a DAF 235. In another embodiment, the NCM may be prepared so as to have self-adhesive properties.

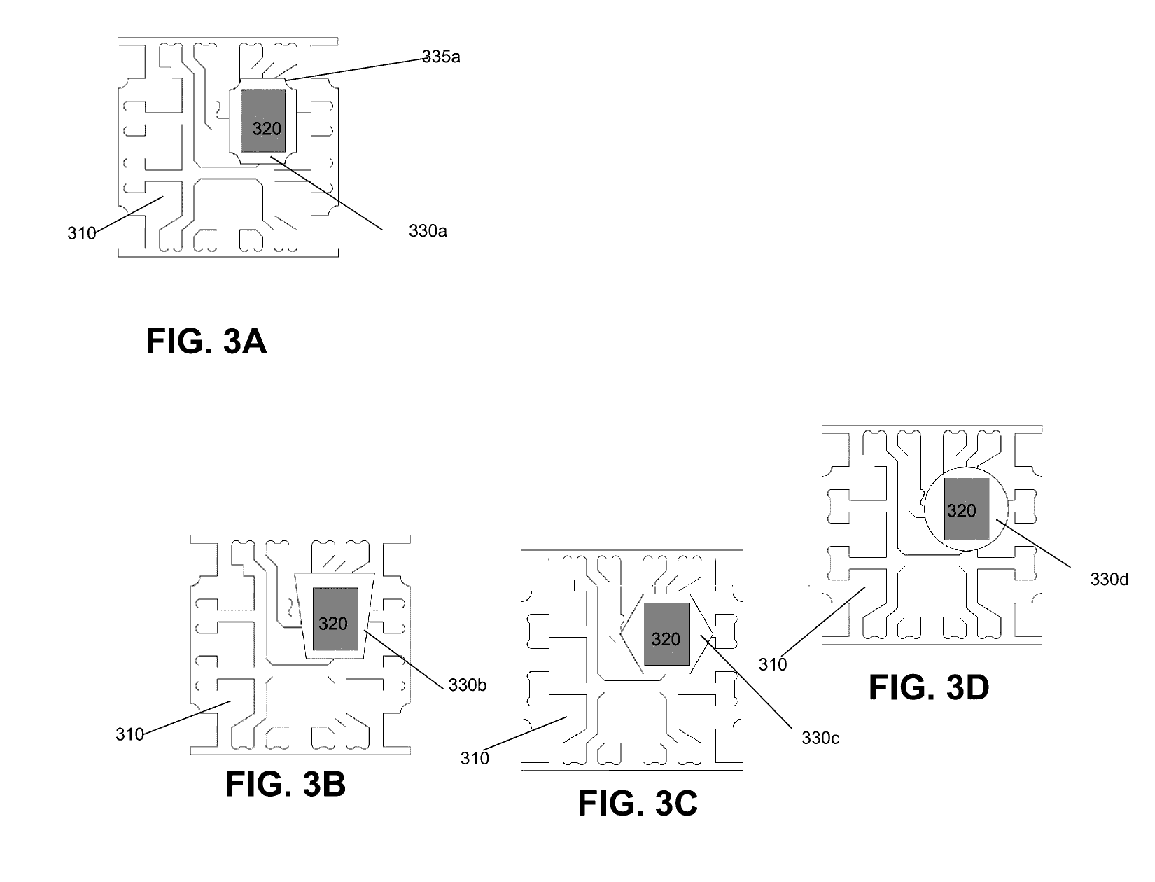

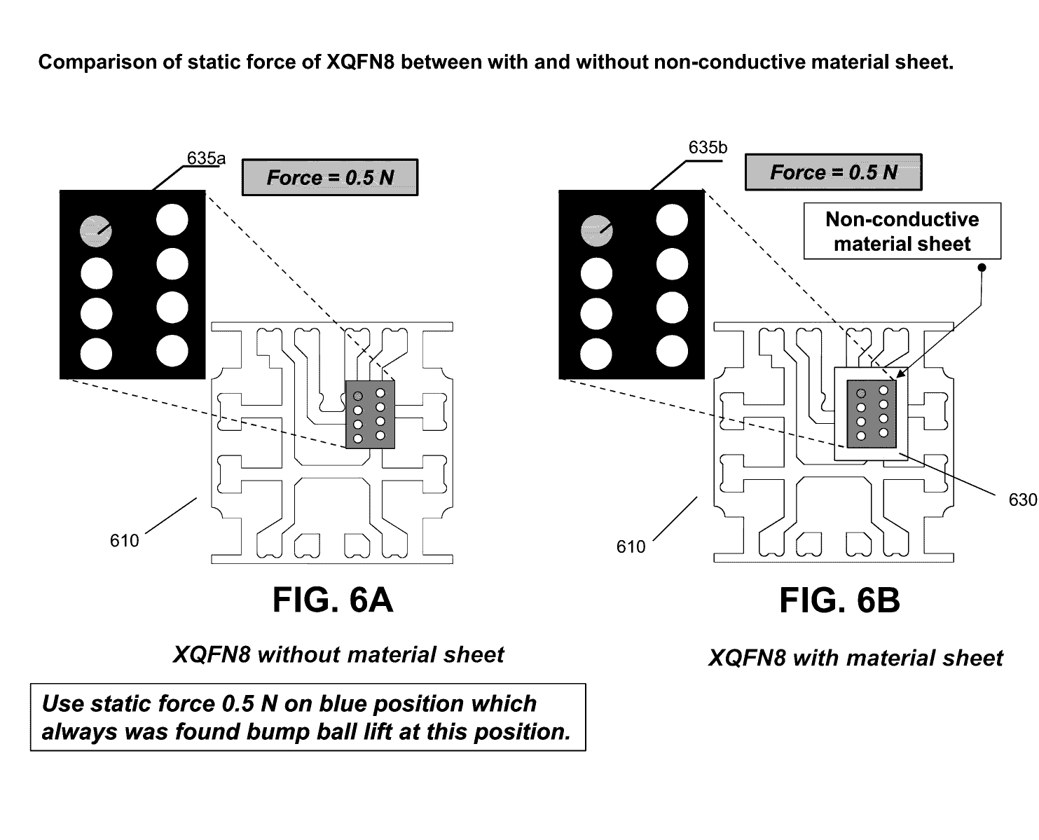

Refer to FIGS. 3A-3D. In example embodiments, a lead frame assembly 310 has a device die 320 placed onto a NCM sheet 330a having a rectangular shape with concave fillet corners 335a. Other shapes, such as a trapezoid 330b, or a hexagon 330c, or a circle 330d, may be used. However, it is likely that a rectangular or square shape is used in that this is the usual shape of the device die. In some circumstances, a customized shape may have additional attributes suitable for package types requiring more bonding area or more strength of the lead frame, and even more resistance to lead bouncing. Further, if one were to use these additional shapes of NCM sheets for a given product device, he would likely characterize the combination of device die, lead frame, wire bonding, encapsulation to determine the critical stress parameters. A discussion illustrating the reduction in stress and displacement for an example package, an XQFN8 is presented in connection with FIGS. 6A-6B, FIGS. 7A-7B, and FIGS. 8A-8B. The techniques presented would be applicable to other combinations.

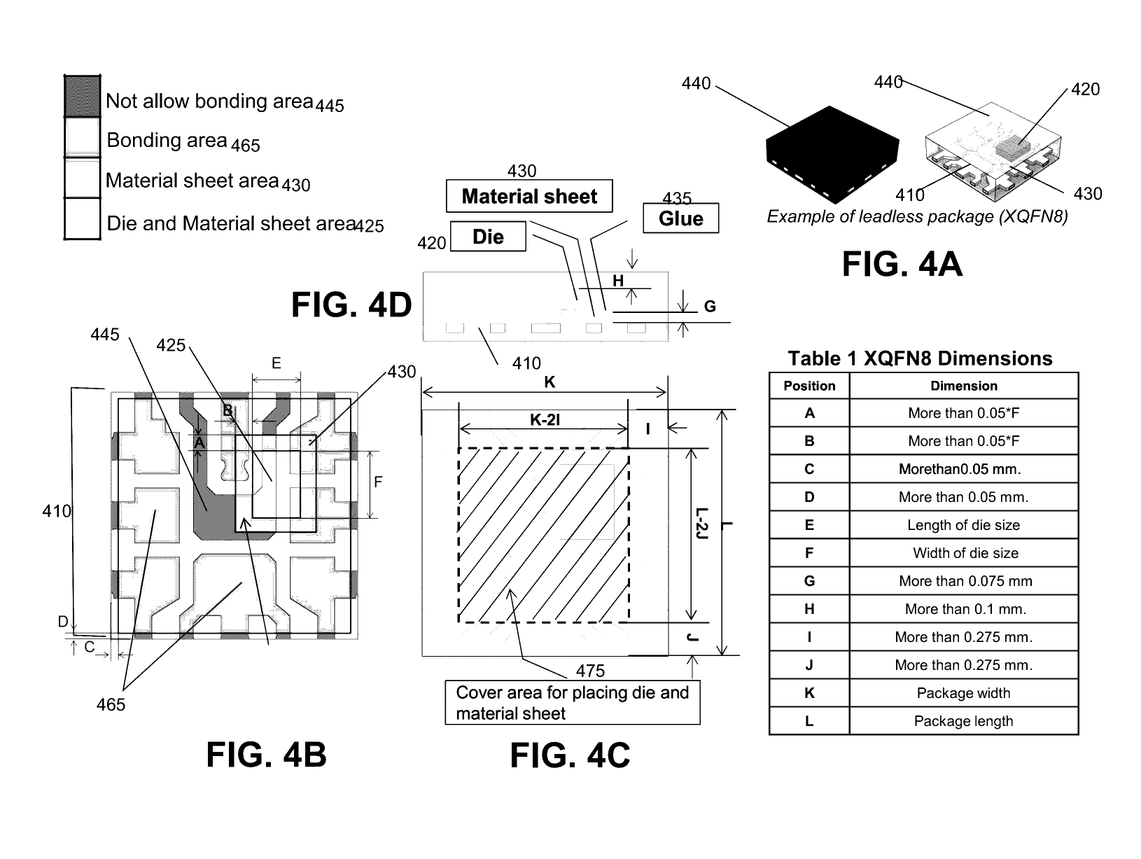

Refer to FIG. 4A. Upon a lead frame assembly 410 in an example leadless package XQFN8, a device die 420 is mounted onto the NCM sheet 430 with a suitable mounting adhesive, in this case glue 435. After assembly, the package is enveloped in a molding compound 440. The example package has dimensions of about 1.6×1.6×0.5 mm (length×width×thickness, respectively). Refer to FIGS. 4B-4D. On the lead frame assembly 410, is area 445. Wire bonding is not permitted owing to the area of excessive stress (which has been previously determined) that causes breakage of the wire bonds on the device die 420. Area 455 is the edge of the lead frame terminals which would not have wire bonds attached. Areas 465 are not excessively susceptible to stress and can receive wire bonds. The device die 420 with the NCM sheet 430 may be placed anywhere in cover area 475 on the lead frame. Table 1 outlines the dimensional relationships between the lead frame assembly 410, device die 420 and NCM sheet 430. For this package type, the NCM sheet dimensions extend 0.05 beyond the length and width of the device die. Further, the thickness of the NCM sheet is greater than or equal to 0.75 mm. This would roughly be about ¾ of the device die 420 thickness which at least 0.1 mm.

TABLE 1
XQFN8 Dimensions

| Position | Dimension |
|---|---|
| A | More than 0.05 x F |
| B | More than 0.05 x E |
| C | More than 0.05 mm |
| D | More than 0.05 mm. |
| E | Length of die size |
| F | Width of die size |
| G | More than 0.075 mm |
| H | More than 0.1 mm. |
| I | More than 0.275 mm. |
| J | More than 0.275 mm. |
| K | Package width |
| L | Package length |

For characterizing a lead frame, XRF (energy dispersive X-ray fluorescence) analysis would be suitable for determining the elements and thickness of the plated layers, or the lead frame manufacturing process (e.g., etching or stamping).

For example, a lead frame having a base metal of copper (Cu) may be pre-plated with NiPd, NiPdAu, etc. The pre-plating has a nickel (Ni) thickness of about 1.5 um, the palladium (Pd) thickness of about 0.152 um, and a thin layer of gold (Au), gold/silver (Au/Ag) or palladium/silver (Pd/Ag).

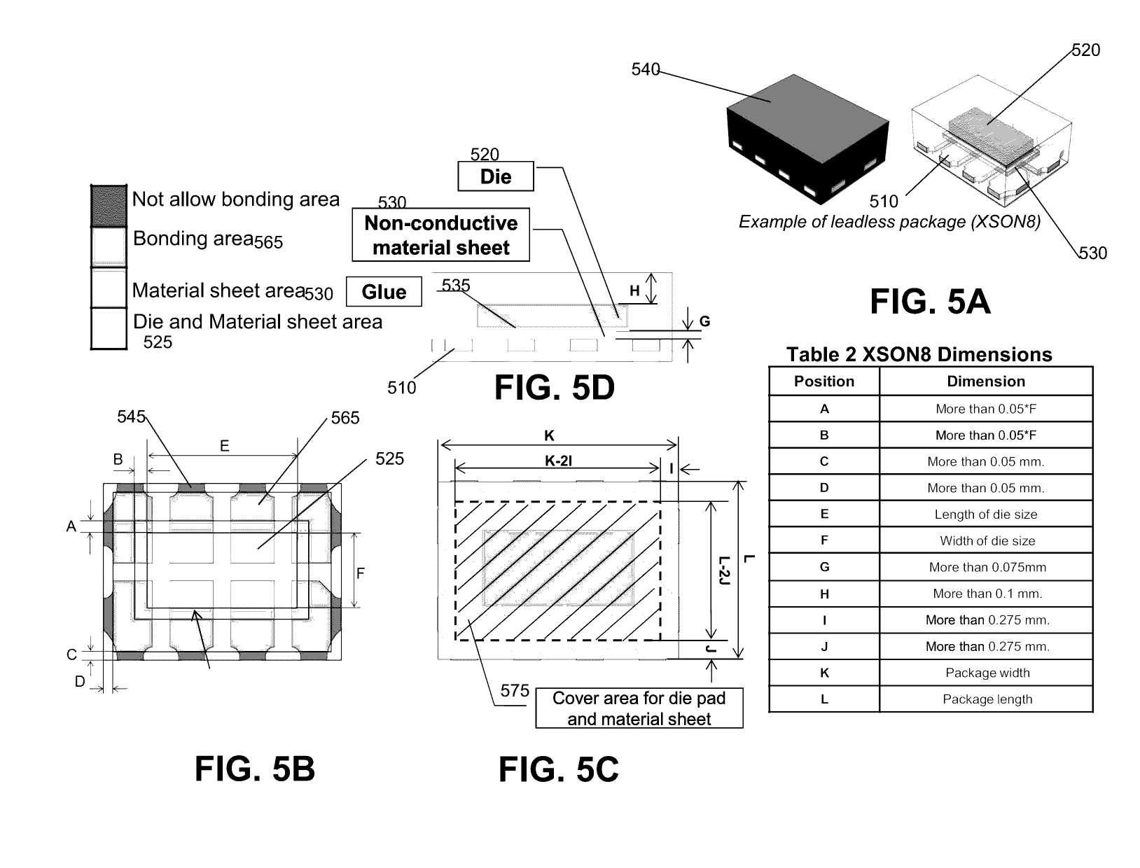

Refer to FIG. 5A. Upon a lead frame assembly 510 in an example leadless package XSON8, a device die 520 is mounted onto the NCM sheet 530 with a suitable mounting adhesive, in this case glue 535. After assembly, the package is enveloped in a molding compound 540. Table 2 outlines the dimensional relationships between the lead frame assembly 510, device die 520 and NCM sheet 530. The example package has dimensions of about 1.35×1.0×0.5 mm (length×width×thickness, respectively). Refer to FIGS. 5B-5D. On the lead frame assembly 510, is area 545, wire bonding is not permitted owing to the area of excessive stress (which is beyond the device die/package boundary). Areas 545 is the edge of the lead frame terminals which would not have wire bonds attached. Areas 565 are not excessively susceptible to stress and can receive wire bonds. The device die 420 with the NCM sheet 530 may be placed anywhere in cover area 575 of the lead frame assembly 510. Table 2 outlines the dimensional relationships between the lead frame assembly 510, device die 520 and NCM sheet 530. For this package type, the NCM sheet dimensions extend 0.05 beyond the length and width of the device die. Further, the thickness of the NCM sheet is greater than or equal to 0.75 mm. This would roughly be about ¾ of the device die 520 thickness which at least 0.1 mm.

TABLE 2
XSON8 Dimensions

| Position | Dimension |
|---|---|
| A | More than 0.05 x F |
| B | More than 0.05 x E |
| C | More than 0.05 mm |
| D | More than 0.05 mm. |
| E | Length of die size |
| F | Width of die size |
| G | More than 0.075 mm |
| H | More than 0.1 mm. |
| I | More than 0.275 mm. |
| J | More than 0.275 mm. |
| K | Package width |
| L | Package length |

Determining the placement of the NCM sheet on the lead frame is a result of characterizing the lead frame by placing a device die at a predetermining location and measuring the forces applied to the lead frame with a device having a NCM sheet attached and with a device not having one. Refer to FIGS. 6A-6B.

FIG. 6A depicts an XQFN8 lead frame assembly 610. A test device die 620 is placed on a predetermined location on the lead frame assembly 610. A particular bond location 635 has been found susceptible to bump ball lifting. A static force of 0.5N is applied on the test device die on this location. The forces and resulting displacement, borne by the lead frame 610 are measured.

FIG. 6B depicts the same XQFN8 lead frame assembly 610. A test device die 620 placed on the same predetermined location on the lead frame assembly 610. However, a NCM sheet 630 is attached to the test device die 620. The same static force of 0.5N is applied on the test device die 620 on this bond location 765. Again, the forces and resulting displacement, borne by the lead frame 610 are measured. The die thickness is about 150 μm and the NCM sheet thickness is about 75 μm.

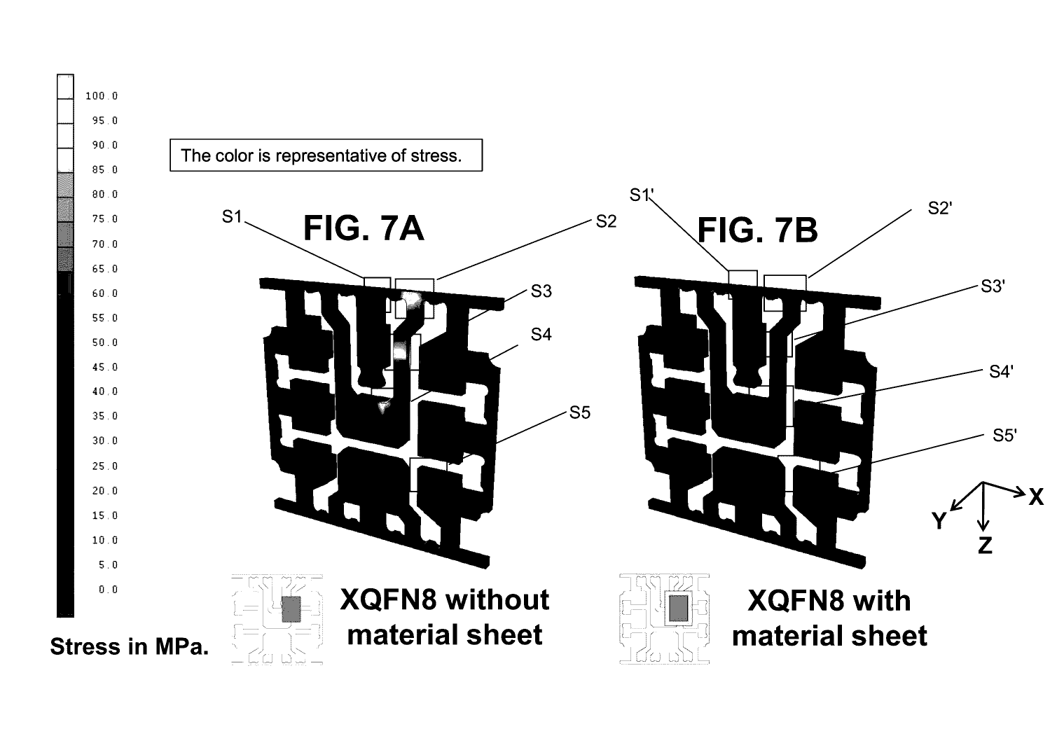

TABLE 3
Stress of Device Die in XQFN 8 Package

| | Stress | | Position | Stress Range | |
|---|---|---|---|---|---|
| Position (S) w/o | Range(MPa) | | (S) with | (MPa) | |
| NCM Sheet | LO | HI | NCM Sheet | LO | HI |
| S1-FIG. 7A | 31 | 52.6 | S1′-FIG. 7B | 8 | 13.5 |
| S2-FIG. 7A | 80 | 114 | S2′-FIG. 7B | 23 | 30 |
| S3-FIG. 7A | 93 | 125 | S3′-FIG. 7B | 20 | 34 |
| S4-FIG. 7A | 112 | 230 | S4′-FIG. 7B | 18.5 | 38.5 |
| S5-FIG. 7A | 0 | 0.016 | S5′-FIG. 7B | 0 | 0.002 |

Refer to FIG. 7A. The XQFN8 lead frame assembly 610 has been stressed as described earlier. The stress distribution (in MPa or 1×10⁶ N/m²) on the lead frame 710 has been plotted as different colors. The range of pressure ranges from 0.0 to about 100.0 MPa. Note that one MPa is 145 pounds force per square inch. Refer to FIG. 7B. In contrast to FIG. 7A. Owing to the NCM sheet placed under the test device die, stress is significantly less.

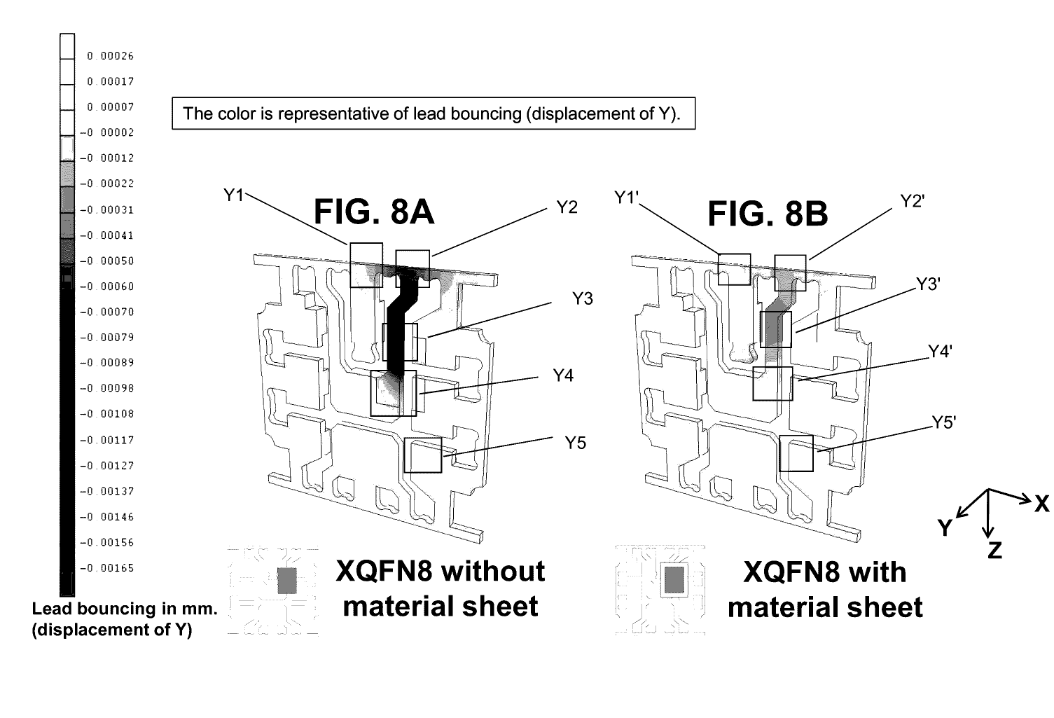

Refer to FIG. 8A. The XQFN8 lead frame assembly 610 has been stressed as described earlier and the measured stress has been described in connection with FIG. 7A. Correlating with the measured stress, the degree of lead bouncing (displacement in the Y-direction) has been noted.

Refer to FIG. 8B. In contrast to FIG. 8A. Owing to the NCM sheet placed under the test device die, lead bouncing was significantly less.

TABLE 4
Lead Bounce of Device Die in XQFN 8 Package

| | Displacement | | Position | Displacement | |
|---|---|---|---|---|---|
| Position | Range | | (Y) | Range | |
| (Y) w/o | (mm) | | with NCM | (mm) | |
| NCM Sheet | LO | HI | Sheet | LO | HI |
| Y1-FIG. 8A | −0.0001 | −0.00024 | Y1′-FIG. 8B | −1.50E−05 | −5.37E−05 |
| Y2-FIG. 8A | −0.0005 | −0.00058 | Y2′-FIG. 8B | −0.00014 | −0.00015 |
| Y3-FIG. 8A | −0.0012 | −0.0015 | Y3′-FIG. 8B | −0.00028 | −0.00033 |
| Y4-FIG. 8A | −0.00014 | −0.0006 | Y4′-FIG. 8B | −0.00009 | −0.000125 |
| Y5-FIG. 8A | 0 | 0 | Y5′-FIG. 8B | 0 | 0 |

In an example embodiment, a particular lead frame may be characterized so as to locate areas having reduced stress and displacement. Within that area, the NCM sheet may be included in the device die attach process to minimize stress even further. FIGS. 4A-4D and FIGS. 5A-5D illustrate example dimensions of the components of the assembled/encapsulated device.

In configuring a lead frame assembly according to the present disclosure, as discussed in reference to FIGS. 6A-6B, there may be one or more particular bonding locations which undergo substantially more stress and displacement than others. It would be necessary to characterize the lead frame assembly and device die combination.

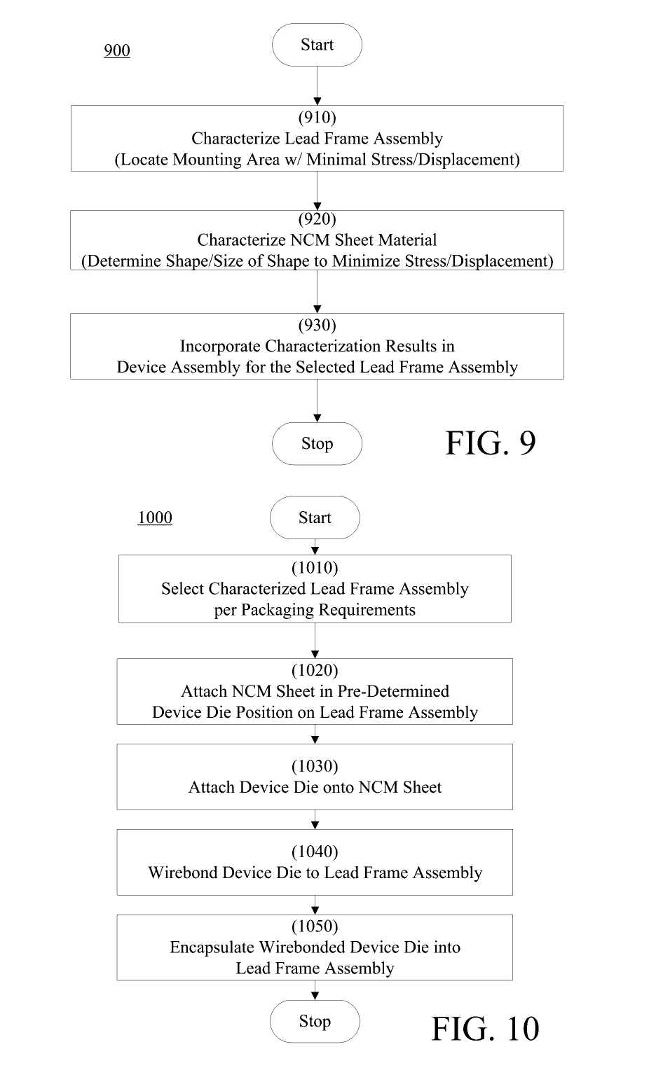

Refer to FIG. 9. In an example embodiment, at step 910, the lead frame assembly and device die combination would undergo a characterization of the stress/displacement distribution. A standard force is applied at one or more locations on the lead frame to which a device die may be attached. As mentioned previously, a 0.5N force was used. These stress/displacement data are gathered and analyzed to find a place in which these parameters are minimized.

To even further reduce the stress/displacement, in step 920, a NCM sheet material is applied to the selected area (i.e., the area of minimal stress/displacement) of the lead frame assembly. With a standard force applied, the resulting stress/displacement are measured. In a lead frame assembly whose stress/displacement has been characterized and an optimum area is location has been found and is useable, the NCM sheet material will further enhance the stability of the die attach and subsequent wire bonds.

In some circumstances, however, the design of the lead frame may not exhibit sufficient resistance to stress/displacement no matter which location is chosen. Due to system requirements, a particular lead frame configuration must be employed. These requirements may include lead frame area and vertical thickness, for example. Thus, a location with the least stress/displacement may not be available.

The use of a NCM sheet material, according to the present disclosure, may be sufficient to reduce the stress/displacement in these situations. In characterizing the NCM sheet, a particular shape may reduce stress/displacement more than other shapes. For a given device die size, rectangular or square shapes may be useful; for others, hexagonal, octagonal, or more sides, etc. may be appropriate. In other cases, the NCM sheet material may be circular and circumscribe the device die. The dimensions of these shapes will exceed the boundary edges of the device die by a prescribed amount; the prescribed amount being determined by characterizing the process.

In step 930, having characterized the lead frame assembly and NCM sheet material, the results are incorporated into the device assembly process.

Refer to FIG. 10. In an example assembly process, modified according embodiments of the present disclosure, a device die with a NCM sheet material mounted thereon, is attached to a lead frame assembly. In step 1010, a characterized lead frame assembly is selected to meet the packaging requirements of a device die and end user. In step 1020, at a pre-determined device die position, a NCM sheet is attached to the lead frame assembly. In step 1030, the device die is mounted onto the NCM sheet. The device die may use glue or a DAF material for adhesion. At step 1040, the device die is wire bonded onto the lead frame assembly. The suitable locations of the wire bonds on the lead frame assembly would have been determined during the characterization of the lead frame. The wire bonds on the lead frame assembly should be in locations with acceptable levels of stress/displacement. After the wire bonding, in step 1050, the device die and lead frame assembly is encapsulated in a molding compound.

The embodiments of the present disclosure may be applied to any micro-electronic packages that have the device die undergo wire bonding or ribbon bonding. The reducing of displacement and stress is applicable to any size bond wired, any loop shape of wire bonding, forward and reverse bonding technique with and without bump balls. Metals such as gold (Au), silver (Ag), copper (Cu), aluminum (Al) and their alloys may be used, but are not limited to theses.

In combination with locating the area on the lead frame exhibiting a minimal amount of stress and displacement, the present disclosure serves to reduce the stress and displacement even further.

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

Numerous other embodiments of the invention will be apparent to persons skilled in the art without departing from the spirit and scope of the invention as defined in the appended claims.

1. A semiconductor device comprising:
a lead frame assembly having a non-conductive material (NCM) sheet placed on a location of the lead frame assembly;
a device die having a length, width, and thickness attached to the NCM sheet, the device die being attached to the NCM with an adhesive;
wherein the NCM sheet has a length and width greater than the length and width of the device die; and
wherein the NCM sheet has a thickness less than the thickness of the device die.

2. The semiconductor device as recited in claim 1, wherein the length and width of the NCM sheet is greater than about 0.10 times the length and about 0.10 times the width of the device die.

3. The semiconductor device as recited in claim 1, wherein the thickness of the NCM sheet is at least three-fourths the thickness of the device die.

4. The semiconductor device as recited in claim 1, wherein the adhesive is selected from the following: die-attach film (DAF), die-attach glue.

5. The semiconductor device as recited in claim 1, wherein the NCM sheet has a shape selected from one of the following: a square, a rectangle, a rectangle with fillet corners, a hexagon, a polygon of greater than six-sides, a circle.

6. The semiconductor device as recited in claim 1, whereby the NCM sheet mitigates wire bond lifting at device die bond pads by reducing bouncing of the wire bond leads owing to stress and movement of the lead frame assembly underneath the device die.

7. A semiconductor device assembled in a leadless package, the leadless package comprising:
a device die having a length, width, and thickness, the device die having a top-side surface with active circuit elements and an underside surface;
a non-conductive material (NCM) sheet having a length and width greater than the length and width of the device die, the NCM attached to the underside surface of the device die; and
a lead frame assembly, the lead frame assembly having been characterized such that the semiconductor device die attached to the NCM is placed in a cover area and where allowed bonding areas and not-allowed bonding areas are defined; and
whereby the NCM sheet mitigates wire bond lifting at device die bond pads by reducing bouncing of the wire bond leads owing to stress and movement of the lead frame assembly underneath the device die.

8. The semiconductor device as recited in claim 7, further comprising,
an adhesive holding the NCM to the underside surface of the device die.

9. The semiconductor device as recited in claim 7, wherein the leadless package is one of the following: XQFN8, XSON8.

10. The semiconductor as recited in claim 7,
wherein the NCM sheet is rectangular,
the length of the NCM sheet is greater than about 0.10 times the length of the device die,
the width of the NCM sheet is greater than about 0.10 times the width of the device die, and
the thickness of the NCM sheet is at least three-fourths the thickness of the device die.

11. A method for assembling a semiconductor device, the method comprising:
selecting a lead frame assembly;
attaching a NCM sheet in a device die position on the lead frame assembly; and
attaching a device die onto the NCM sheet.

12. The method as recited in claim 11, further comprising,
wire bonding the device die to the lead frame assembly; and
encapsulating the device die and lead frame assembly.

13. The method as recited in claim 12,
wherein the lead frame assembly is for a leadless package, and the lead frame assembly has been characterized such that the device die attached to the NCM is placed in a cover area and where allowed bonding areas and not-allowed bonding areas are defined;
wherein the device die has a length, width, and thickness, the device die having a top-side surface with active circuit elements and an underside surface
wherein the NCM sheet has a length and width greater than the length and width of the device die, the NCM attached to the underside surface of the device die; and
whereby the NCM sheet mitigates wire bond lifting at device die bond pads by reducing bouncing of the wire bond leads owing to stress and movement of the lead frame assembly underneath the device die.

14. The method as recited in claim 11, wherein the device die position on the lead frame assembly has been found by a characterization of the lead frame,
whereby the device die position is a location having substantially reduced stress and displacement with respect to other positions on the lead frame assembly.

15. The method as recited in claim 14, where the substantially reduced stress and displacement are at a minimum.

16. The semiconductor device as recited in claim 7, wherein the device die position on the lead frame assembly is a location having substantially reduced stress and displacement with respect to other positions on the lead frame assembly.

17. The semiconductor device as recited in claim 7, where the substantially reduced stress and displacement are at a minimum.
